(19) United States
(12) Patent Application Publication
(10) Pub. No.: US 2008/0160752 A1
(43) Pub. Date: Jul. 3, 2008

(54) METHOD FOR CHIP TO PACKAGE INTERCONNECT

(75) Inventors: Lawrence Clevenger, LaGrangeville, NY (US); Timothy J. Dalton, Ridgefield, CT (US); Mukta Ghate Farooq, Hopewell Junction, NY (US); William Francis Landers, Wappingers Falls, NY (US); Carl Radens, LaGrangeville, NY (US); Chih-Chao Yang, Glenmont, NY (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 11/619,384

(22) Filed: Jan. 3, 2007

(51) Int. Cl. H01L 21/44

(52) U.S. Cl. 438/614; 257/E21.476

(57) ABSTRACT

A damascene method of forming a C4 element includes forming a last level metal layer on a substrate, forming a TV ILD layer on the last level metal layer, forming a lithographically patterned UBM adhesion layer including one of Ti, TiW, Cr and Cu, forming a mandrel layer over the UBM adhesion layer, lithographically patterning the mandrel layer to form an aperture, depositing a solder layer by one of sputtering, evaporation, physical vapor deposition, solder wave or injection molding in the aperture, planarizing the solder layer by CMP, removing the mandrel layer, reflowing the solder to ball the solder to form a ball interconnect, and joining a second substrate with an I/O pad to the ball interconnect.

### BACKGROUND OF THE INVENTION

1. Field of the Invention

The present invention relates to a method and apparatus for a controlled collapse chip connection (C4). In particular, the present invention describes a damascene process for forming a controlled collapse chip connection (C4) element.

2. Description of the Related Art

Current C4 (Controlled Collapse Chip Connection) methods primarily use plating to deposit the solder alloy. This may be done using a seed layer followed by a resist process, further followed by electrolytic plating. The seed layer typically contains the UBM (Under Bump Metallurgy) or part of the UBM. An example of UBM layers is a combination of TiW/CrCu/Cu deposited by sputtering. This is followed by electrolytic plating of a Sn/Pb alloy using a resist stencil. The resist defines the areas where the plating will occur. Subsequently, the resist is removed, and exposed seed layers are etched using wet or dry etching methods. The solder may then be sent through a high temperature furnace to allow it to melt and assume a near-spherical shape. The conventional process is depicted in FIG. 1. Starting with the final hard dielectric level in the wafer fabrication, the steps of the conventional patterning TV Nitride/Oxide (CF4 RIE) and cap nitride; depositing final metallization Al layer (500 A TaN/250 A Ti/250 A TiN/1.2 um AlCu); patterning TD Al using resist and RIE processes; depositing polyimide (or PSPI) and pattern; depositing the BLM (Ball Limiting Metallurgy) (or UBM (Under Bump Metallurgy)) layer (e.g. 1000-2000 A TiW/1000-2000 A CrCu/4000-5000 ACu); depositing a resist and pattern is (resist lamination and photolithography); plating the C4 (e.g. Sn/Pb or Pb-free, e.g. Sn or SnCu or SnAg or SnAgCu); stripping the resist; etching the BLM (wet); ashing (conductive haze removal); reflowing to ball the C4; and testing the C4.

The problem with the conventional process is that its use is limited to those solder alloys which can be deposited by an electrolytic plating process.

### SUMMARY OF THE INVENTION

In view of the foregoing and other exemplary problems, drawbacks, and disadvantages of the conventional methods and structures, an exemplary feature of the present invention is to provide a method and system for forming a C4 element, where the selection of the C4 metal is not constrained by the electrochemistry of plating.

In a first aspect of the present invention, a damascene method of forming a C4 element includes forming a last level metal layer on a substrate, forming a TV ILD layer on the last level metal layer, forming a lithographically patterned UBM adhesion layer including one of Ti, TiW, and CrCu, forming a mandrel layer over the UBM adhesion layer, lithographically patterning the mandrel layer to form an aperture, depositing a solder layer by one of sputtering, evaporation, physical vapor deposition, solder wave or injection molding in the aperture, planarizing the solder layer by CMP, removing the mandrel layer, reflowing the solder to ball the solder to form a ball interconnect, and joining a second substrate with an I/O pad to the ball interconnect.

The present invention uses a damascene process to form a C4 element in place of the conventional plating technique. Accordingly, selection of the C4 metal is not constrained by the electrochemistry of plating (e.g., the present invention may use additional eutectic alloys). Specifically, the present invention may use lead-free, Sn-based systems such as SnAgCu, SnCu and SnZn (drop-in for SnPb eutectic alloys because of the similarity in eutectic temperature). Also, the present invention also provides improved EM resistance relative to other Pb-free alternatives. The present invention enables the elimination of the BLM (TiW/CrCu/Cu) underlayer, which allows for a simplified forming process. Finally, the present invention enables the saving of a lithography level by pattering the TV dielectric at the same time as the mandrel layer.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1 illustrates a conventional technique for forming C4 element; and

FIGS. 2-8 illustrate a method of forming a C4 element for a chip to package interconnect in accordance with an exemplary embodiment of the present invention.

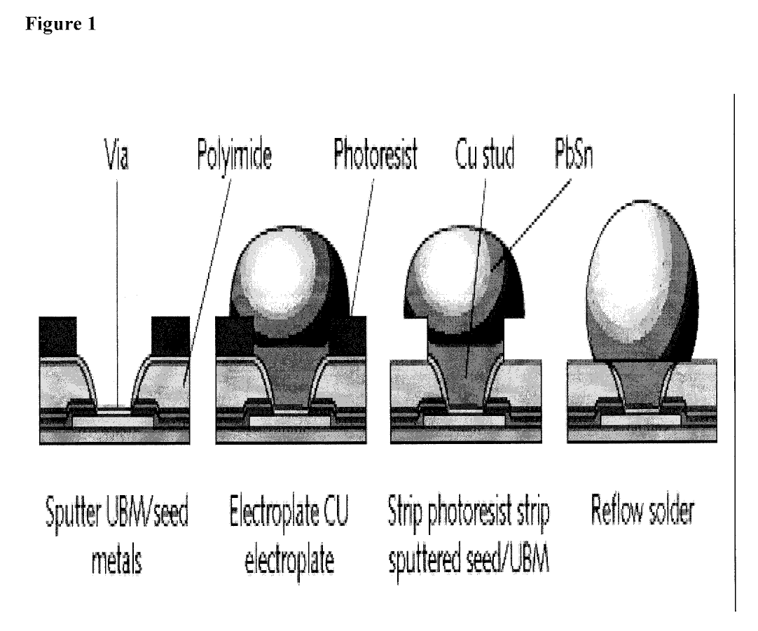

### DETAILED DESCRIPTION OF EXEMPLARY EMBODIMENTS OF THE INVENTION

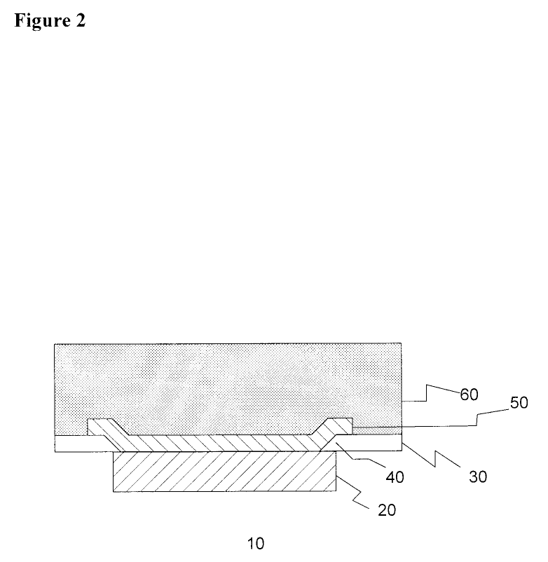

Referring now to the drawings, and more particularly to FIGS. 2-8, there are shown exemplary embodiments of the method and structures according to the present invention.

FIGS. 2-8 illustrate a method for the formation of a chip-to-package interconnect. In place of the conventional plating technique, a damascene process is used to form a C4 element. Accordingly, selection of C4 metal is not constrained by the electrochemistry of plating.

As illustrated in FIG. 2, a last level metal, or last level of copper to be deposited, 20 is formed on a substrate 10. A TV (hard passivation) ILD (Inter Level Dielectric) 40 is formed on the last level metal 20. A UBM adhesion layer 50 is lithographically patterned on the TV ILD layer 40. The UBM adhesion layer 50 may include a material selected from Ti, TiW and/or CrCu and/or Cu and/or Ni. A mandrel 60 is formed on the UBM adhesion layer 30.

Layer 20 is the final level of copper. It is formed by depositing copper metal in the via created in the underlying dielectric level, and following with a CMP planarizing step. A typical thickness for layer 20 is 1 to 3 micrometers. Layer 40 is the final hard passivation. It is formed by depositing the desired thicknesses of oxide and nitride, followed by lithography and RIE to pattern those layers. A typical thickness for layer 40 is 0.5 to 2 micrometers. Layer 50 is the terminal metal level, typically Aluminum or Al—Cu, where the Cu is less than 1% by weight. It too is deposited, and then patterned using photolithography and RIE. A liner layer may be used under the Aluminum layer to improve adhesion. The liner may consist of a combination of Ti, TiN, Ta, TaN, or some elements thereof A typical thickness for layer 50 is 1 to 3 micrometers.

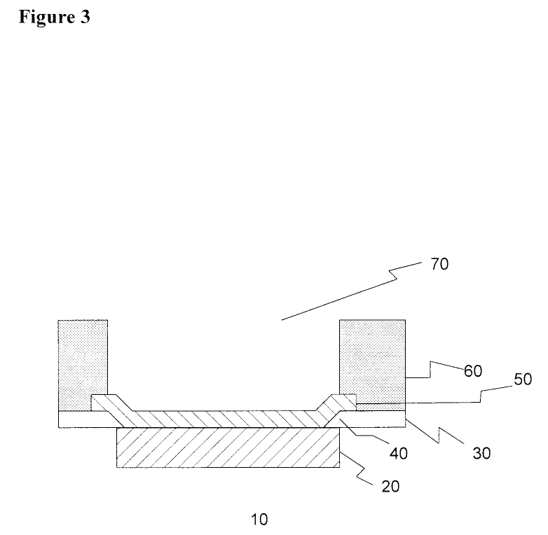

As shown in FIG. 3, the mandrel layer 60 is a lithographically-defined sacrificial mandrel material which can be a polyimide (5811, BPDA), kapton (PMDA-ODA), a spin-on material, CVD W, or other sacrificial material. The mandrel 60 may have a thickness in a range of 40 um to 100 um, and preferably a thickness of 50 um. Providing the mandrel 60 within this thickness range allows a desired volume of solder to be deposited. The mandrel 60 is patterned to yield an aperture 70. The aperture is formed having a size of 35 to 70 micrometers, which depends on the pitch, in other words, separation of the centers of nearest neighbor apertures.

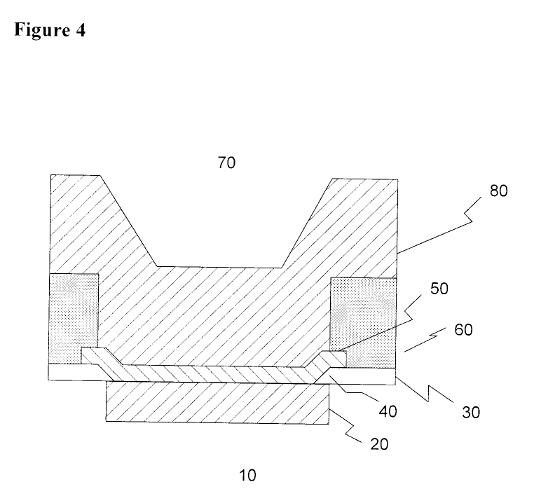

A metal 80 (“solder”) is deposited using physical means such as sputtering, evaporation, physical vapor deposition, solder wave, or IMS injection molding (e.g., see FIG. 4). A height of deposited material may be as much as twice the height of the mandrel 60. The material of the metal solder 80 may be anything that acts as an electrical interconnection between the chip and the package. It could be a standard solder alloy made of Sn and Pb, or it could be a different metal or alloy or other material that can function as an electrical interconnect in a flip chip configuration.

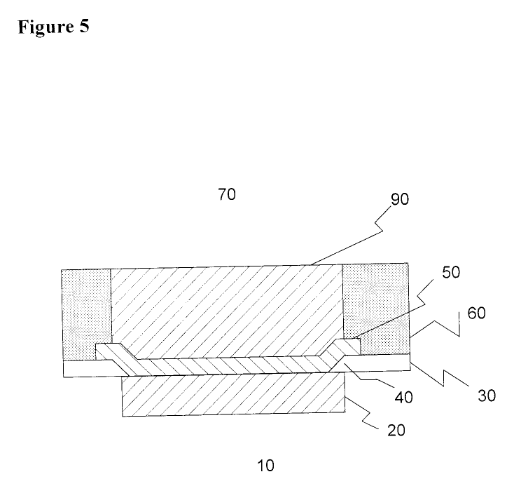

The metal solder layer 80 is then planarized by CMP or other means with a well-controlled total volume for subsequent reflow (e.g., see FIG. 5).

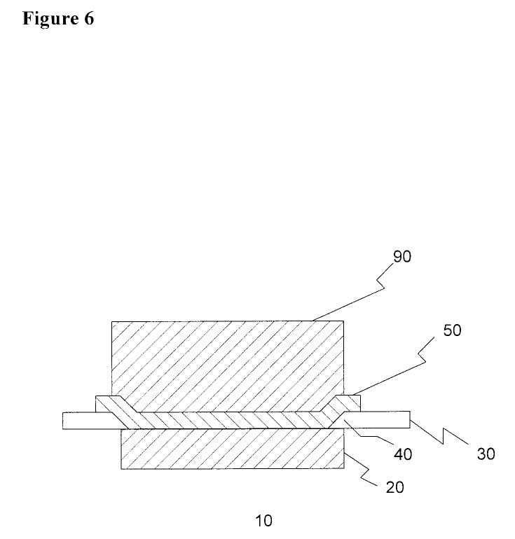

Next, the remaining mandrel layer 60 is removed (e.g., see FIG. 6) by chemical dissolution or a RIE process or a physical removal method. Any removal method, however, may be used as long as it does not significantly attack the metal solder 80 or other materials on the chip.

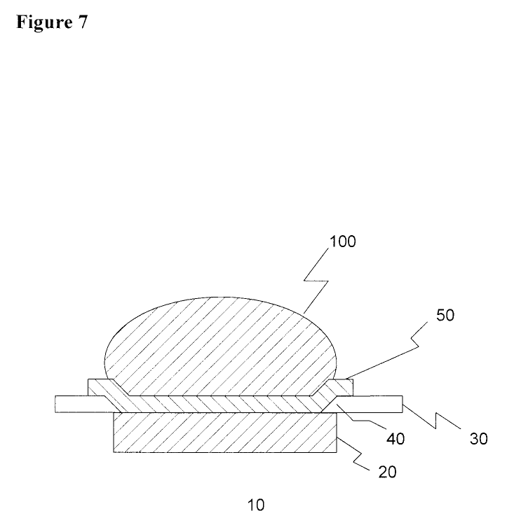

Next, the metal solder layer 80 is subjected to high-temperature reflow to ball the solder to form a reflow interconnect 100 (e.g., see FIG. 7). A temperature high includes any temperature high enough to cause complete melting (i.e. at least just above the liquidus temperature of the solder alloy).

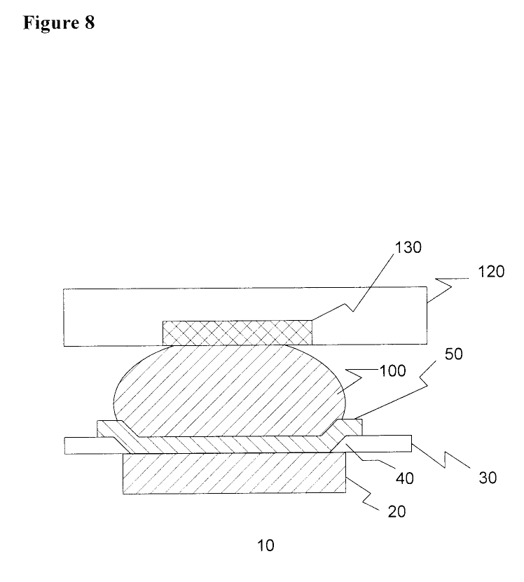

Finally, a second substrate 120 with an I/O pad 130 is joined to the reflow interconnect (e.g., see FIG. 8).

In an alternative embodiment, a spherical particle of alloy material may be disposed within a lithographically-formed aperture to create a C4 component. In another alternative embodiment, an assemblage, slurry, agglomerate, paste, emulsion, or group of particles of alloy material may be disposed within a lithographically-formed aperture to create a C4 component. In another alternative embodiment, an additional passivation layer may be formed over the chip substrate before or after the formation of the C4 element.

As indicated above, using the present invention, selection of the C4 metal is not constrained by the electrochemistry of plating (e.g., the present invention may use additional eutectic alloys). Specifically, the present invention may use lead-free, Sn-based systems such as SnAgCu, SnCu and SnZn (drop-in for SnPb eutectic alloys). Also, the present invention provides improved EM resistance relative to other Pb-free alternatives. The present invention enables the elimination of the BLM (TiW/CrCu/Cu) underlayer, which allows for a simplified forming process. Finally, the present invention enables the saving of a lithography level by pattering the TV dielectric at the same time as the mandrel layer.

While the invention has been described in terms of several exemplary embodiments, those skilled in the art will recognize that the invention can be practiced with modification within the spirit and scope of the appended claims.

Further, it is noted that, Applicants' intent is to encompass equivalents of all claim elements, even if amended later during prosecution.

1. A damascene method of forming a C4 element for a chip-to-package interconnect, said method comprising:
forming a last level metal layer on a substrate;
forming a hard passivation inter layer dielectric layer on the last level metal layer;
forming a lithographically patterned under bump metallurgy (UBM) adhesion layer comprising one of Ti, TiW and CrCu;
forming a mandrel layer over the UBM adhesion layer;
lithographically patterning the mandrel layer to form an aperture;
depositing a solder layer by sputtering;
planarizing the solder layer by CMP;
removing the mandrel layer;
reflowing the solder to ball the solder to form a ball interconnect; and
joining a second substrate with an I/O pad to the ball interconnect,
wherein said solder layer comprises Sn, Ag, and Cu,
wherein said mandrel layer comprises kapton,
wherein said solder layer is reflowed at a temperature in a range of 183° C. to 375° C.,
wherein said solder layer is deposited directly on said mandrel layer,
wherein said C4 element is devoid of a ball limiting metallurgy layer, and
wherein said hard passivation inter layer dielectric is patterned simultaneously with said mandrel layer to reduce a number of lithography levels.

2-17. (canceled)
